(19) United States
(12) Patent Application Publication
(10) Pub. No.: US 2026/0262389 A1
(43) Pub. Date: Sep. 3, 2026

(54) DISPLAY APPARATUS HAVING A LIGHT-EMITTING DEVICE, A BANK INSULATING LAYER AND AN ENCAPSULATION STRUCTURE

(71) Applicant: LG Display Co., Ltd., Seoul (KR)

(72) Inventors: Min Soo PARK, Paju-si (KR); Young Sik KIM, Paju-si (KR)

(21) Appl. No.: 19/405,417

(22) Filed: Dec. 2, 2025

(30) Foreign Application Priority Data
Feb. 28, 2025 (KR) 10-2025-0026637

(51) Int. Cl. H10K 59/122; H10K 59/80

(52) U.S. Cl. CPC H10K 59/122; H10K 59/873

(57) ABSTRACT

A display apparatus including light-emitting devices disposed on emission areas of a device substrate, an encapsulation structure disposed on the light-emitting devices, the encapsulation structure including an organic encapsulating layer, and a bank insulating layer disposed between the light-emitting device and the encapsulation structure, the bank insulating layer including bank openings and bank grooves, in which each of the emission areas defined by the bank openings has a curved planar shape, and each of the bank grooves extends from one of the bank openings in an outward direction of the corresponding bank opening.

### CROSS REFERENCE TO RELATED APPLICATION

This application claims priority from and the benefit of Korean Patent Application No. 10-2025-0026637, filed on February 28, 2025, which is hereby incorporated by reference for all purposes as if fully set forth herein.

### BACKGROUND

### Field

Embodiments of the invention relate generally to a display apparatus in which an encapsulation structure is disposed on a light-emitting device and a bank insulating layer.

### Discussion of the Background

Generally, a display apparatus provides an image to a user. For example, the display apparatus can include a light-emitting device. The light-emitting device can emit light displaying a specific color. For example, the light-emitting device can include a light-emitting unit disposed between a first electrode and a second electrode.

The light-emitting device can be disposed on an emission area of a device substrate. The emission area can be defended by a bank insulating layer. For example, the bank insulating layer can include a bank opening overlapping with the emission area. An encapsulation structure can be disposed on the light-emitting device and the bank insulating layer. Thus, in the display apparatus, damage of the light-emitting device due to external impact and moisture can be prevented. For example, the encapsulation structure can include an encapsulating layer.

The above information disclosed in this Background section is only for understanding of the background of the inventive concepts, and, therefore, it may contain information that does not constitute prior art.

### SUMMARY

Display apparatuses according to the embodiments of the invention are capable of preventing the occurrence of spots due to an unfilled area of the organic encapsulating layer, while also decreasing a thickness of the encapsulation structure.

Additional features of the inventive concepts will be set forth in the description which follows, and in part will be apparent from the description, or may be learned by practice of the inventive concepts.

According to one or more embodiments of the invention, a display apparatus includes: light-emitting devices disposed on emission areas of a device substrate; an encapsulation structure disposed on the light-emitting devices, the encapsulation structure including an organic encapsulating layer; and a bank insulating layer disposed between the device and the encapsulation structure, the bank insulating layer including bank openings and bank grooves. Each of the emission areas is defined by the bank openings and has a curved planar shape. Each of the bank grooves extends from one of the bank openings in an outward direction of the corresponding bank opening.

A plane of each of the bank grooves may include an area having a straight shape.

A plane of each of the emission areas may have a circular shape.

A width of a plane of each bank groove may be less than a diameter of each emission area.

Each of the bank openings may contact the same bank groove as the bank opening adjacent in a direction.

A plane of each of the bank grooves may have a shape in which a width decreases as it moves away from the corresponding bank opening.

According to yet another embodiment of the invention, a display apparatus includes a device substrate including: an emission area having a curved planar shape; a light-emitting device including a first electrode, a light-emitting unit, and a second electrode, which are sequentially stacked on the emission area; a bank insulating layer disposed outside the emission area, the bank insulating layer covering an edge of the first electrode; and an encapsulation structure disposed on the light-emitting device and the bank insulating layer, the encapsulation structure including an organic encapsulating layer. The bank insulating layer includes a first bank region and a second bank region. The first bank region is disposed adjacent to the emission area. The second bank region is disposed outside the first bank region. The first bank region includes a first sub-region and a second sub-region. The second sub-region has a smaller thickness than the first sub-region. Each of the first sub-region and the second sub-region includes a portion overlapping with the first electrode.

Each of the first sub-region and the second sub-region may include an upper surface opposite to the device substrate. An upper surface of the second sub-region may be disposed closer to the device substrate than an upper surface of the first sub-region.

The first sub-region and the second sub-region may be repeatedly arranged along an edge of the emission area.

Each of the first sub-region and the second sub-region may include a portion disposed outside the first electrode. A thickness of the second bank region may be substantially equal to a thickness of the first sub-region disposed outside the first electrode.

The bank insulating layer may include a first bank layer and a second bank layer. The second bank layer can be disposed on the first bank layer. The second bank layer may include a material have an etching selectivity with respect to the first bank layer.

The first bank layer may include an absorbing material.

The second bank layer may be disposed outside the second sub-region.

A thickness of the second sub-region may increase in a direction away from the emission area.

A width of the second sub-region may decrease in a direction away from the emission area.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a view schematically showing a display apparatus according to an embodiment of the invention.

FIG. 2 is a view showing an equivalent circuit of a pixel area in the display apparatus according to an embodiment of the invention.

FIG. 3 is an enlarged view of the K region in FIG. 1.

FIG. 4 is a cross-sectional view taken along I-I’ of FIG. 3.

FIG. 5 and FIG. 6 are enlarged views of the K region in FIG. 1 according to other embodiments of the invention.

FIG. 7 is an enlarged view of the K region in FIG. 1 according to another embodiment of the invention.

FIG. 8 is a cross-sectional view taken along II-II’ of FIG. 7.

FIG. 9 is a cross-sectional view taken along III-III’ of FIG. 7.

FIG. 10 is a cross-sectional view taken along I-I’ of FIG. 3 according to another embodiment of the invention.

FIG. 11 and FIG. 12 are enlarged views of the K region in FIG. 1 according to other embodiments of the invention.

FIG. 13 is a cross-sectional view taken along II-II’ of FIG. 7 according to another embodiment of the invention.

FIG. 14 is a cross-sectional view taken along I-I’ of FIG. 3 according to another embodiment of the invention.

FIG. 15 is a perspective view a display device according to another embodiment of the invention.

FIG. 16 is a cross-sectional view taken along I-I’ of FIG. 3 of the embodiment of FIG. 15.

FIG. 17 is a cross-sectional view taken along I-I’ of FIG. 3 of a variation of the embodiment of FIG. 15.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

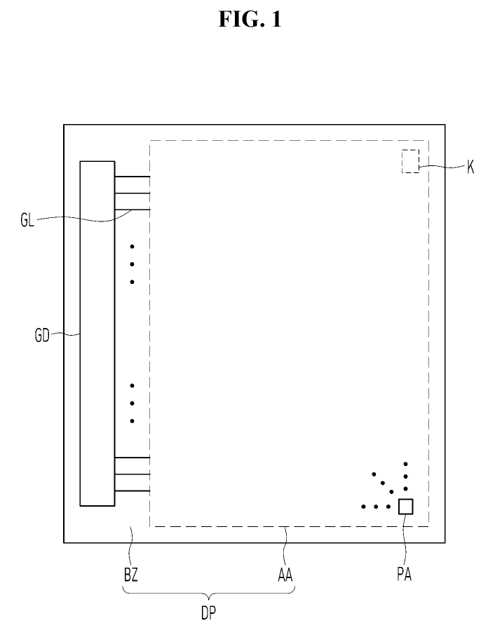

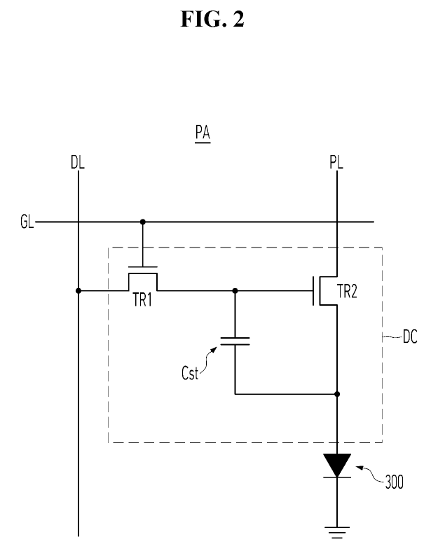

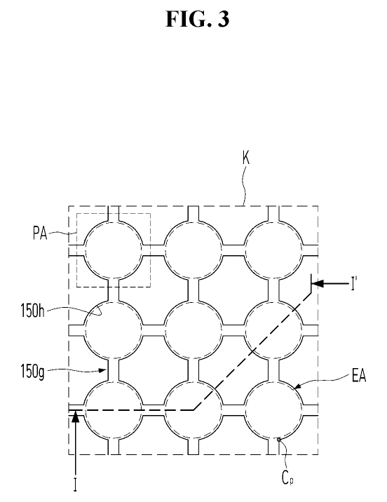

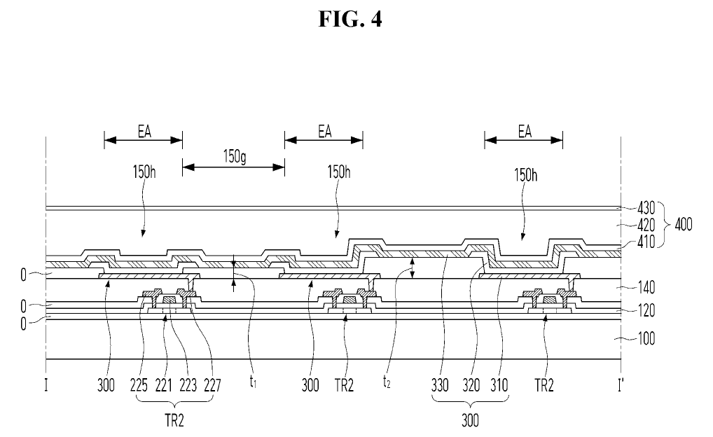

FIG. 1 is a view schematically showing a display apparatus according to an embodiment of the invention. FIG. 2 is a view showing an equivalent circuit of a pixel area in the display apparatus according to an embodiment of the invention. FIG. 3 is an enlarged view of K region in FIG. 1. FIG. 4 is a cross-sectional view taken along I-I’ of FIG. 3.

Referring to FIGS. 1 to 4, the display apparatus according to an embodiment of the invention may include a display panel DP. The display panel DP can generate an image provided to a user. For example, the display panel DP may include a plurality of pixel areas PA. Various signals can be applied to each pixel area PA through signal wirings GL, DL, and PL. For example, the signal wirings GL, DL, and PL may include gate lines GL applying a gate signal, data lines DL applying a data signal, and power voltage supply lings PL supplying a first power voltage.

A gate driver GD electrically connected to the gate lines GL, a data driver electrically connected to the data lines DL, and a power unit electrically connected to the power voltage supply lines PL may be spaced apart from the plurality of pixel areas PA. For example, the display panel DP may include an active area AA in which the plurality of pixel areas PA are disposed and a bezel area BZ disposed outside the active area AA, and the gate driver GD, the data driver and the power unit may be disposed outside the active area AA. The active area AA may be surrounded by the bezel area BZ. At least one of the gate driver GD, the data driver (not shown), and the power unit may be disposed in the bezel area BZ. For example, the display apparatus according to an embodiment of the invention may be a GIP (Gate In Panel) type display apparatus in which the gate driver GD is formed in the bezel area BZ.

Each of the pixel areas PA can display a specific color. For example, a driving circuit DC electrically connected to the signal lines GL, DL, and PL and a light-emitting device 300 electrically connected to the driving circuit DC may be disposed in each pixel area PA. The operation of the light-emitting device 300 may be controlled by the driving circuit DC. For example, the driving circuit DC may supply a driving current corresponding to the data signal to the light-emitting device 300 according to the gate signal using the first power voltage. The driving current applied to the light-emitting device 300 by the driving circuit DC may be maintained for one frame. For example, in the display apparatus according to an embodiment of the invention, the driving circuit DC may include a first thin film transistor TR1, a second thin film transistor TR2, and a storage capacitor Cst.

The first thin film transistor TR1 may transmit the data signal to the second thin film transistor TR2 according to the gate signal. For example, the first thin film transistor TR1 may function as a switching thin film transistor. The first thin film transistor TR1 may include a first semiconductor pattern, a first gate electrode, a first drain electrode, and a first source electrode. For example, the first gate electrode may be electrically connected to one of the gate lines GL, and the first drain electrode may be electrically connected to one of the date lines DL. The source electrode may be electrically connected to the first drain electrode through the first semiconductor pattern according to a signal applied to the first gate electrode.

The second thin film transistor TR2 may generate the driving current corresponding to the data signal using the first power voltage. For example, the second thin film transistor may can function as a driving thin film transistor. The second thin film transistor TR2 may include a second semiconductor pattern 221, a second gate electrode 223, a second drain electrode 225, and a second source electrode 227, as shown in FIG. 4. For example, the second gate electrode 223 may be electrically connected to the first source electrode of first thin film transistor TR1, and the second drain electrode 225 may be electrically connected to one of the power voltage supply lines PL. A channel region of the second semiconductor pattern 211 may have an electrical conductivity corresponding to a voltage of a signal applied to the second gate electrode 223.

The voltage of the signal applied to the second gate electrode 223 of the second thin film transistor TR2 may be maintained by the storage capacitor Cst for one frame. The storage capacitor Cst may have a stacked structure of capacitor electrodes. For example, the storage capacitor Cst may have a structure in which a first capacitor electrode electrically connected to the second gate electrode 223 and a second capacitor electrode electrically connected to the second source electrode 227 are stacked.

The driving circuit DC of each pixel area PA may be supported by a device substrate 100. The device substrate 100 may include an insulating material. For example, the device substrate 100 may include glass or plastic. At least one insulating layer 110, 120, 130, 140, and 150 for preventing unintended electrical connection may be disposed on the device substrate 100. For example, a buffer insulating layer 110, a gate insulating layer 120, an interlayer insulating layer 130, a planarization layer 140, and a bank insulating layer 150 may be disposed on the device substrate 100.

The buffer insulating layer 110 may be disposed close to an upper surface of the device substrate 100. For example, the buffer insulating layer 110 may be in direct contact with the upper surface of the device substrate 100. The gate insulating layer 120 may be disposed on the buffer insulating layer 110. For example, the second semiconductor pattern 221 of each pixel area PA may be disposed between the buffer insulating layer 110 and the gate insulating layer 120. The interlayer insulating layer 130 may be disposed on the gate insulating layer 120. For example, the second gate electrode 223 of the second thin film transistor TR2 in each pixel area PA may be disposed between the gate insulating layer 120 and the interlayer insulating layer 130. The planarization layer 140 may be disposed on the interlayer insulating layer 130. For example, the second drain electrode 225 and the source electrode 227 of the second thin film transistor TR2 in each pixel area PA may be disposed between the interlayer insulating layer 130 and the planarization layer 140.

The buffer insulating layer 110, the gate insulating layer 120, the interlayer insulating layer 130, and the planarization layer 140 may include an insulating material. The planarization layer 140 may include a material having a higher fluidity than the buffer insulating layer 110, the gate insulating layer 120, and the interlayer insulating layer 130. For example, the buffer insulating layer 110, the gate insulating layer 120, and the interlayer insulating layer 130 may be an inorganic insulating layer made of an inorganic insulating material, and the planarization layer 140 may be an organic insulating layer made of an organic insulating material. A thickness difference due to the driving circuit DC of each pixel area PA may be mitigated by the planarization layer 140. For example, an upper surface of the planarization layer 140 opposite to the device substrate 100 may be formed flat.

The light-emitting device 300 of each pixel area PA may be disposed on the upper surface of the planarization layer 140. The light-emitting device 300 of each pixel area PA may be electrically connected to the second source electrode 227 of the second thin film transistor TR2 in the corresponding pixel area PA. Thus, in the display apparatus according to an embodiment of the invention, the light-emitting device 300 of each pixel area PA can emit light displaying a specific color using the driving current generated by the driving circuit DC of the corresponding pixel area PA. For example, in the display apparatus according to an embodiment of the invention, the light-emitting device 300 of each pixel area PA may include a first electrode 310, a light-emitting unit 320, and a second electrode 330, which are sequentially stacked on the planarization layer 140.

The first electrode 310 and the second electrode 330 may include a conductive material. The second electrode 330 may include a different material from the first electrode 310. For example, the second electrode 330 may have a higher transmittance than the first electrode 310. A reflectance of the first electrode 310 may be higher than a reflectance of the second electrode 330. For example, the first electrode 310 may include metal, such as aluminum (Al) and silver (Ag), and the second electrode 330 may be a transparent electrode made of a transparent conductive material, such as ITO and IZO.

The light-emitting unit 320 can generate light having luminance corresponding to a voltage difference between the first electrode 310 and the second electrode 330. For example, the light-emitting unit 320 may include at least one emission material layer (EML). The emission material layer may include an organic emission material, an inorganic emission material, or a hybrid emission material. Light generated by the light-emitting unit 320 may be emitted through the second electrode 330.

The bank insulating layer 150 may be disposed on the upper surface of the planarization layer 140. The bank insulating layer 150 may include an insulating material. The first electrode 310 of the light-emitting device 300 in each pixel area PA may be insulated from the first electrode 310 of the light-emitting device 300 in an adjacent pixel area PA by the bank insulating layer 150. For example, an edge of the first electrode 310 of the light-emitting device 300 in each pixel area PA may be covered by the bank insulating layer 150. The bank insulating layer 150 may partially expose the first electrode 310 of the light-emitting device 300 in each pixel area PA. For example, the bank insulating layer 150 may include bank openings 150h overlapping with a central region of the first electrode 310 on each pixel area PA.

The light-emitting unit 320 of the light-emitting device 300 in each pixel area PA may be in direct contact with the central region of the first electrode 310 of the light-emitting device 300 in the corresponding pixel area PA exposed by the one of the bank openings 150h. The second electrode 330 of the light-emitting device 300 in each pixel area PA may be in direct contact with the light-emitting unit 320 of the light-emitting device 300 in the corresponding pixel area PA. Thus, in the display apparatus according to an embodiment of the invention, the light-emitting unit 320 of the light-emitting device 300 in each pixel area PA can generate light within one of the bank openings 150h. More particularly, in the display apparatus according to an embodiment of the invention, an emission area EA in which light is generated may be defined in each pixel area PA by the bank openings 150h of the bank insulating layer 150. The bank insulating layer 150 may be disposed outside the emission area EA of each pixel area PA in some embodiments.

The first electrode 310 of the light-emitting device 300 in each pixel area PA may be electrically connected to the second source electrode 227 of the second thin film transistor TR2 corresponding to the pixel area PA at the outside of the emission area EA defined in the corresponding pixel area PA. Thus, in the display apparatus according to an embodiment of the invention, the central region of the first electrode 310 overlapping with the emission area EA of each pixel area PA may be in direct contact with the upper surface of the planarization layer 140. More particularly, in the display apparatus according to an embodiment of the invention, an upper surface of the first electrode 310 opposite to the device substrate 100 in each pixel area PA may be flat within the emission area EA of the corresponding pixel area PA. In this manner, luminance deviation arising from positional differences in light generation within the emission area EA of each pixel area PA may be prevented.

Each of the bank openings 150h may have a curved planar shape. A plane of the emission area EA defined in each pixel area PA may have a shape corresponding to a plane of the corresponding bank opening 150h. For example, each of the bank openings 150h and the emission area EA of each pixel area PA may have a circular planar shape. Thus, in the display apparatus according to an embodiment of the invention, the emission area EA of each pixel area PA does not include an angled edge. In this manner, a flare phenomenon occurring at an angled edge of the emission area EA may be prevented. Therefore, in the display apparatus according to an embodiment of the invention, luminance deviation arising from positional differences in emitting location of the light generated in the emission area EA of each pixel area PA may be prevented.

The bank insulating layer 150 may include bank grooves 150g. Each of the bank grooves 150g may be in direct contact with one of the bank openings 150h. For example, a plane of each bank groove 150g may have a shape extending outward from one of the bank openings 150h. A plane of each bank groove 150g may have a smaller width than a plane of each bank opening 150h. For example, a width of the plane of each bank groove 150g may be less than a diameter of the emission area EA of each pixel area PA having a circular planar shape. The plane of each bank groove 150g may include a region having a straight shape. For example, the plane of each bank groove 150g may have a bar shape extending in one direction. The plane of each bank groove 150g may have a constant width. Each of the bank grooves 150g may have a constant depth. Each of the bank grooves 150g may be disposed between the bank openings 150h. A length of each bank groove 150g may be the same as a distance between the bank openings 150h adjacent in a direction. For example, each of the bank openings 150h may be in direct contact with a same bank groove 150g as the bank opening 150h adjacent in a direction. More particularly, adjacent bank openings 150h may directly contact the same bank groove 150g disposed between the adjacent bank openings 150.

The bank grooves 150g may have a shape in which an upper portion of the bank insulating layer 150 is recessed. For example, the bank insulating layer 150 may include a region having a first thickness t1 formed by the bank grooves 150g and a region having a second thickness t2 greater than the first thickness t1. A region of the bank insulating layer 150 having the second thickness t2 may be disposed outside the bank grooves 150g. An edge of the first electrode 310 of the light-emitting device 300 in each pixel area PA may overlap with at least one of the bank grooves 150g. The bank grooves 150g may not overlap with the emission area EA of each pixel area PA. For example, an edge of the first electrode 310 of the light-emitting device 300 in each pixel area PA may not be exposed by the bank grooves 150g. Thus, in the display apparatus according to an embodiment of the invention, a planar shape of the emission area EA defined in each pixel area PA may not be changed by the bank grooves 150g. Therefore, in the display apparatus according to an embodiment of the invention, the flare phenomenon due to the bank grooves 150g can be prevented.

A signal applied to the second electrode 330 of the light-emitting device 300 in each pixel area PA may be the same as a signal applied to the second electrode 330 of the light-emitting device 300 in adjacent pixel area PA. For example, a second power voltage may be applied to the second electrode 330 of the light-emitting device 300 in each pixel area PA. The second power voltage may be different from the first power voltage. For example, the first power voltage may be a positive power voltage (VDD), and the second power voltage may be a negative power voltage (VSS). The second electrode 330 of the light-emitting device 300 in each pixel area PA may be electrically connected to the second electrode 330 of the light-emitting device 300 in adjacent pixel area PA. The second electrode 330 of the light-emitting device 300 in each pixel area PA may be formed simultaneously with the second electrode 330 of the light-emitting device 300 in adjacent pixel area PA. For example, the second electrode 330 of the light-emitting device 300 in each pixel area PA may be in direct contact with the second electrode 330 of the light-emitting device 300 in adjacent pixel area PA. Thus, in the display apparatus according to an embodiment of the invention, a process of forming the second electrode 330 of the light-emitting device 300 in each pixel area PA can be simplified.

An encapsulation structure 400 may be disposed on the light-emitting device 300 of each pixel area PA. The encapsulation structure 400 may prevent the damage of the light-emitting devices 300 in each pixel area PA due to external moisture and impact. The light-emitting device 300 of each pixel area PA may be completely covered by the encapsulation structure 400. For example, the encapsulation structure 400 may include a region overlapping with the emission area EA of each pixel area PA and a region overlapping with a non-emission area disposed between the emission areas EA. The bank openings 150h of the bank insulating layer 150 may be filled with the encapsulation structure 400.

The encapsulation structure 400 may include inorganic encapsulating layers 410 and 430, and at least one organic encapsulating layer 420 between the inorganic encapsulating layers 410 and 430. For example, the encapsulation structure 400 may include a first inorganic encapsulating layer 410, an organic encapsulating layer 420, and a second inorganic encapsulating layer 430, which are sequentially stacked. The first inorganic encapsulating layer 410, the organic encapsulating layer 420, and the second inorganic encapsulating layer 430 may include an insulating material. The organic encapsulating layer 420 may include a material having a higher fluidity than the first inorganic encapsulating layer 410 and the second inorganic encapsulating layer 430. For example, the first inorganic encapsulating layer 410 and the second inorganic encapsulating layer 430 may be an inorganic insulating layer made of an inorganic insulating material, and the organic encapsulating layer 420 may be an organic insulating layer made of an organic insulating material. A thickness difference due to the light-emitting device 300 of each pixel area PA can be mitigated by the organic encapsulating layer 420. For example, an upper surface of the organic encapsulating layer 420 opposite to the device substrate 100 may be flat.

The organic encapsulating layer 420 may be formed by a coating process. Thus, in the display apparatus according to an embodiment of the invention, the organic encapsulating layer 420 may move along a curved edge of each bank opening 150h due to high fluidity. For example, the organic encapsulating layer 420 may not be introduced into the inside of each bank opening 150h through a region of the corresponding bank opening 150h having a curved shape. Rather, the organic encapsulating layer 420 may be introduced into the inside of each bank opening 150h through a region Cp (FIG. 3) of the corresponding bank opening 150h which is in contact with one of the bank grooves 150g. For example, the region Cp of the corresponding bank opening 150h which is in contact with one of the bank grooves 150g may be an angled edge. In the display apparatus according to an embodiment of the invention, the organic encapsulating layer 420 can be moved to the inside of the bank openings 150h in contact with one of the bank grooves 150g through a region of the corresponding bank groove 150g having a straight shape. Accordingly, a path through which the organic encapsulating layer 420 moves toward the inside of the bank openings 150h can be diversified by the bank grooves 150g. In this manner, in the display apparatus according to an embodiment of the invention, an area that is not filled with the organic encapsulating layer 420 in the inside of the bank openings 150h, which overlaps with the emission areas EA having a curved planar shape, may be prevented.

Accordingly, the display apparatus according to an embodiment of the invention may include the light-emitting devices 300 on the emission areas EA of the device substrate 100, the bank insulating layer 150 disposed outside the emission areas EA, and the encapsulation structure 400 on the light-emitting devices 300 and the bank insulating layer 150. The bank including layer 150 may include the bank openings 150h overlapping with the emission areas EA and the bank grooves 150g extending outward from each bank opening 150h. Each of the emission areas EA defined by the bank openings 150h may have a curved planar shape, and the encapsulation structure 400 may include the organic encapsulating layer 420. Thus, in the display apparatus according to an embodiment of the invention, the flare phenomenon due to an angled edge of the emission areas EA, and an area that is not filled with the organic encapsulating layer 420 in the inside of the bank openings 150h may not occur. Therefore, in the display apparatus according to an embodiment of the invention, the occurrence of spots due to an unfilled area of the organic encapsulating layer 420 can be prevented, and thus, the quality of the image provided to the user can be improved.

As described above, a path through which the organic encapsulating layer 420 moves toward the inside of the bank openings 150h may be diversified by the bank grooves 150g. Thus, in the display apparatus according to an embodiment of the invention, the inside of the bank openings 150h may be quickly filled with the organic encapsulating layer 420. Accordingly, the time for a process of forming the organic encapsulating layer 420 and a thickness of the organic encapsulating layer 420 to prevent the occurrence of an unfilled area of the organic encapsulating layer 420 may be reduced. For example, in the display apparatus according to an embodiment of the invention, a thickness of the encapsulation structure 400 may be reduced. Therefore, in the display apparatus according to an embodiment of the invention, low power operating may be achieved, and power consumption can be reduced by reducing loss of the light due to the encapsulation structure 400.

The driving circuit DC of each pixel area PA according to an embodiment is exemplarily described as including the first thin film transistor TR1, the second thin film transistor TR2, and the storage capacitor Cst. However, in the display apparatus according to another embodiment of the invention, the driving circuit DC of each pixel area PA may include a driving thin film transistor and a plurality of switching thin film transistors. For example, in the display apparatus according to another embodiment of the invention, the driving circuit DC of each pixel area PA may further include a third thin film transistor to initialize the storage capacitor Cst of the corresponding pixel area PA according to the gate signal. The third thin film transistor may include a third semiconductor pattern, a third gate electrode, a third drain electrode, and a third source electrode. For example, the third gate electrode may be electrically connected to one of the gate lines GL, the third drain electrode may be electrically connected to an initial line applying an initial signal, and the third source electrode may be electrically connected to the storage capacitor Cst. Thus, in the display apparatus according to another embodiment of the invention, the degree of freedom in the configuration of the driving circuit DC in each pixel area PA may be improved.

In the display apparatus according to embodiments of the invention, the location and the electrical connection of the first drain electrode, the first source electrode, the second drain electrode 225, and the second source electrode 227 of each driving circuit DC may vary depending on the configuration of the corresponding driving circuit DC and/or the type of the corresponding thin film transistors TR1 and TR2. For example, in the display apparatus according to another embodiment of the invention, the second gate electrode 223 of each driving circuit DC may be electrically connected to the first drain electrode of the corresponding driving circuit DC. Thus, in the display apparatus according to another embodiment of the invention, the degree of freedom in the configuration of each driving circuit DC and the type of each thin film transistor TR1 and TR2 may be improved.

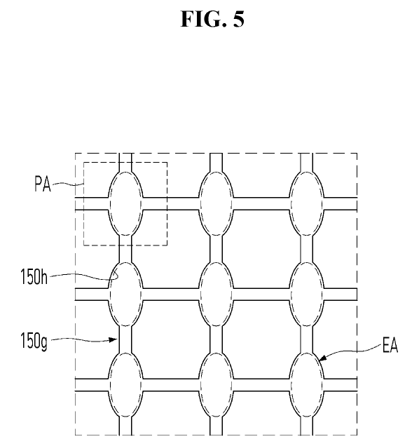

The display apparatus according to an embodiment of the invention is described such that each of the bank openings 150h and the emission area EA of each pixel area PA have a circular planar shape. However, in the display apparatus according to another embodiment of the invention, the emission area EA of each pixel area PA may have various shapes made of a curved surface. For example, in the display apparatus according to another embodiment of the invention, the emission area EA of each pixel area PA may have an elliptical planar shape, as shown in FIG. 5. The emission area EA of each pixel area PA may have a planar shape corresponding to one of the bank openings 150h. For example, a plane of each of the bank openings 150h may have an elliptical shape. Thus, in the display apparatus according to an embodiment of the invention, the degree of freedom in the planar shape of each emission area EA defined in each pixel area PA can be improved.

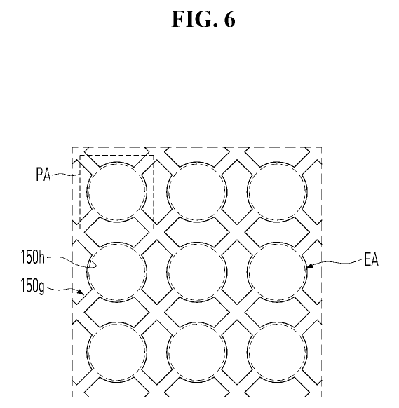

The display apparatus according to an embodiment of the invention is described such that each of the bank grooves 150g is spaced apart from adjacent bank groove 150g. However, in the display apparatus according to another embodiment of the invention, the bank grooves 150g can be variously arranged. For example, in the display apparatus according to another embodiment of the invention, a plane of each bank groove 150g may have a shape extending toward each emission area EA from a specific point surrounded by the emission areas EA, as shown in FIG. 6. Thus, in the display apparatus according to another embodiment of the invention, the degree of freedom in the planar shape of each of the bank grooves 150g can be improved.

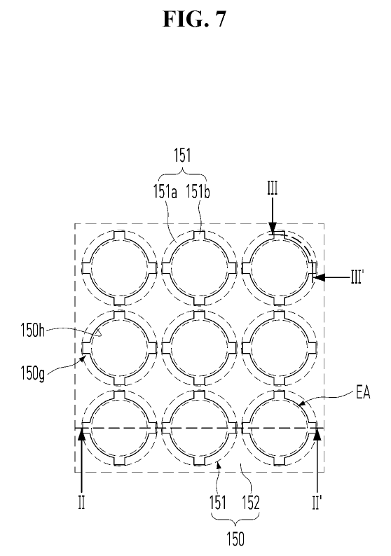

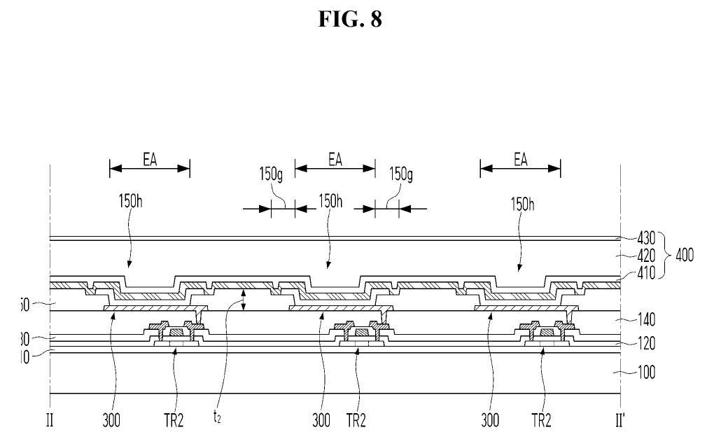

The display apparatus according to an embodiment of the invention is described such that each of the bank grooves 150g is in direct contact with two bank openings 150h adjacent in a direction. However, in the display apparatus according to another embodiment of the invention, each of the bank grooves 150f may be in direct contact with only one of bank openings 150h. For example, in the display apparatus according to another embodiment of the invention, the bank insulating layer 150 may include bank regions 151 disposed adjacent to the emission areas EA and a second bank region 152 disposed outside the first bank regions 151. Each of the first bank regions 151 may include a first sub-region 151a and a second sub-region 151b having a smaller thickness than the first sub-region 151a, as shown in FIGS. 7 to 9.

The second sub-region 151b of each first bank region 151 may be formed by the bank grooves 150g. For example, an upper surface of the second sub-region 151b opposite to the device substrate 100 may be disposed closer to the device than an upper surface of the first sub-region 151a opposite to the device substrate 100. The first sub-region 151a and the second sub- region 151b of each first bank region 151 may be in direct contact with one of the emission areas EA. For example, the first sub-region 151a and the second sub-region 151b of each first bank region 151 may include a portion overlapping with the first electrode 310 in one of the emission areas EA. A plurality of first sub-regions 151a and a plurality of second sub-regions 151b may be disposed in each first bank region 151. For example, the first sub-region 151a and the second sub-region 151b of each first bank region 151 may be repeatedly arranged along an edge of one of the emission areas EA.

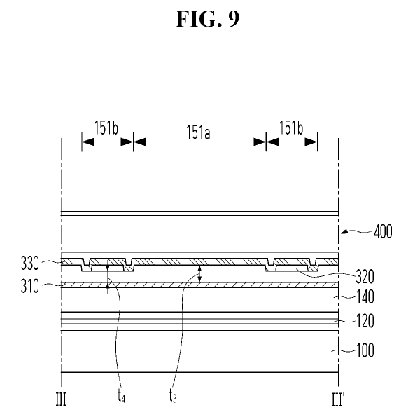

A thickness t4 of the second sub-region 151b on the first electrode 310 may be smaller than a thickness t3 of the first sub-region 151a on the first electrode 310, as shown in FIG. 9. The first sub-region 151a and the second sub-region 151b of each first bank region 151 may include a portion disposed outside the first electrode 310 disposed on one of the emission areas EA. For example, a side surface of the first electrode 310 on each emission area EA may be covered by the first sub-region 151a or the second sub-region 151b of the first bank region 151 that is in contact with the corresponding emission area EA. A thickness of the second sub-region 151b at the outside of the first electrode 310 may be smaller than a thickness of the first sub-region 151a at the outside of the first electrode 310. For example, the first sub-region 151a at the outside of the first electrode 310 may have a same thickness as the second bank region 152. The second bank region 152 may have the second thickness t2. Thus, in the display apparatus according to another embodiment of the invention, the degree of freedom in the shape of the bank insulating layer 150 can be improved.

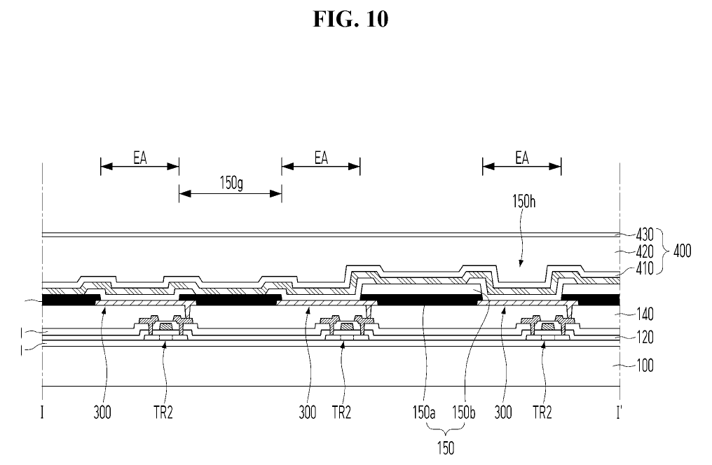

The display apparatus according to an embodiment of the invention is described such that the bank insulating layer 150 has a single-layer structure. However, in the display apparatus according to another embodiment of the invention, the bank insulating layer 150 may have a multi-layer structure. For example, in the display apparatus according to another embodiment of the invention, the bank insulating layer 150 may have a stacked structure of a first bank layer 150a and a second bank layer 150b, as shown in FIG. 10. The second bank layer 150b may be disposed on the first bank layer 150a. The first bank layer 150a may be disposed between the planarization layer 140 and the second bank layer 150b.

An edge of the first electrode 310 of the light-emitting device 300 in each emission area EA may be covered by the first bank layer 150a. The first bank layer 150a may include an absorbing material capable of blocking light. For example, the first bank layer 150a may include a black dye, such as carbon black. Thus, in the display apparatus according to another embodiment of the invention, light emitted toward a direction parallel to the upper surface of the planarization layer 140 from the light-emitting device 300 of each emission area EA may be blocked by the first bank layer 150a. Therefore, in the display apparatus according to another embodiment of the invention, the unintended mixing of light can be prevented.

The second bank layer 150b may include a different material from the first bank layer 150a. For example, the second bank layer 150b may include a material having an etching selectively with respect to the first bank layer 150a. Thus, in the display apparatus according to another embodiment of the invention, damage to the first bank layer 150a due to a solution used in an etching process of the second bank layer 150b may be prevented. The bank grooves 150g may be formed in the second bank layer 150b. For example, a process of forming the bank grooves 150g may include a process of removing a portion of the second bank layer 150b. Each of the bank grooves 150g may completely penetrate the second bank layer 150b. For example, an upper surface of the first bank layer 150a opposite to the device substrate 100 may be partially exposed by the bank grooves 150g. The second bank layer 150b may be disposed outside the second sub-region formed by the bank grooves 150g. Therefore, in the display apparatus according to another embodiment of the invention, changes in the shape of each emission area EA due to a process of forming the bank grooves 150g can be prevented.

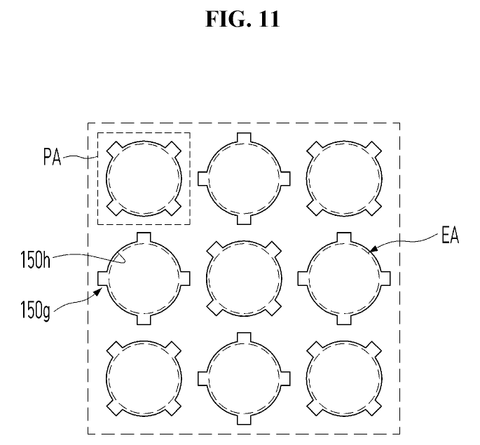

The display apparatus according to an embodiment of the invention is described such that the bank openings 150h and the bank grooves 150g are arranged to have a constant shape. However, in the display apparatus according to another embodiment of the invention, the arrangement of the bank grooves 150g that is in contact with each bank opening 150h may be different from the arrangement of the bank grooves 150g that is in contact with adjacent bank opening 150h. For example, in the display apparatus according to another embodiment of the invention, the emission areas EA may be defined to be disposed side-by-side in a first direction and a second direction perpendicular to the first direction, a plurality of bank grooves 150g may be disposed along an edge of each bank openings 150h, and the location of the bank grooves 150g that are in contact with each bank opening 150h may be different from the location of the bank grooves 150g that are in contact with the bank opening 150h adjacent to the corresponding bank openings 150h in the first direction or the second direction, as shown in FIG. 11. Thus, in the display apparatus according to another embodiment of the invention, the degree of freedom in the arrangement of the bank openings 150h and the bank grooves 150g can be improved.

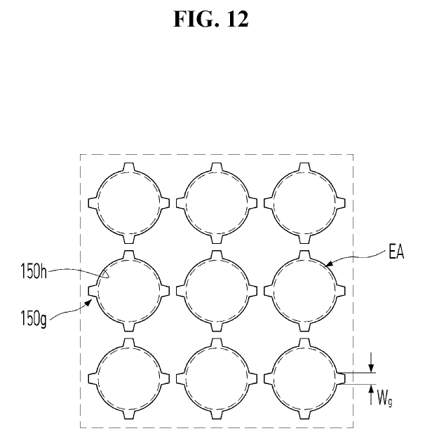

In the display apparatus according to another embodiment of the invention, the plane of each bank groove 150g may have various shapes for smooth inflow of the organic encapsulating layer 420. For example, in the display apparatus according to another embodiment of the invention, a width of each bank groove 150g may decrease as it moves away from the bank opening 150h that is in contact with the corresponding bank groove 150g, as shown in FIG. 12. A width Wg of an end of each bank groove 150g that is in contact with one of the bank openings 150h may be larger than a width of another end of each bank groove 150g disposed far from the corresponding bank opening 150h. Thus, in the display apparatus according to another embodiment of the invention, the organic encapsulating layer 420 introduced into each bank groove 150g through a region of the corresponding bank groove 150g having a straight shape may quickly move inside the bank openings 150h that is in contact with the corresponding bank groove 150g. Therefore, in the display apparatus according to another embodiment of the invention, the occurrence of spots due to the unfilled area of the organic encapsulating layer 420 can be effectively prevented.

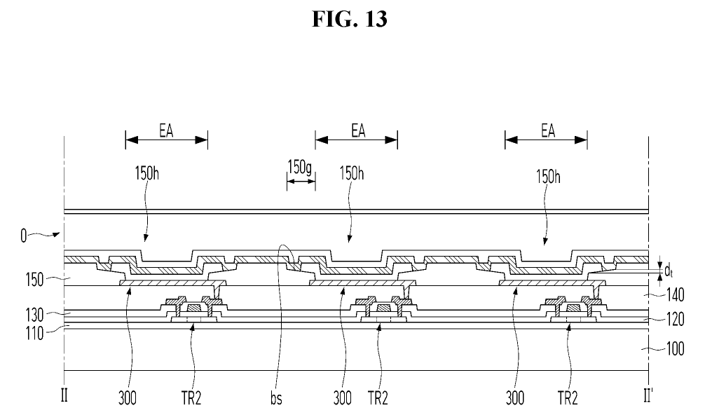

In the display apparatus according to another embodiment of the invention, the cross-section of each bank groove 150g may have various shapes for smooth inflow of the organic encapsulating layer 420. For example, in the display apparatus according to another embodiment of the invention, a thickness of each bank groove 150g may increase as it moves away from the bank opening 150h that is in contact with the corresponding bank groove 150g, as shown in FIG. 13. That is, in the display apparatus according to another embodiment of the invention, a bottom surface bs of each bank groove 150g can have an inclination. The inclination of the bottom surface ‘bs’ of each bank groove 150g may be determined by a thickness difference ‘dt’ of the corresponding bank groove 150g. Thus, in the display apparatus according to another embodiment of the invention, the organic encapsulating layer 420 introduced into each bank groove 150g through a region of the corresponding bank groove 150g having a straight shape may quickly move inside the bank openings 150h that is in contact with the corresponding bank groove 150g. Therefore, in the display apparatus according to another embodiment of the invention, a thickness of the encapsulation structure 400 can be effectively reduced.

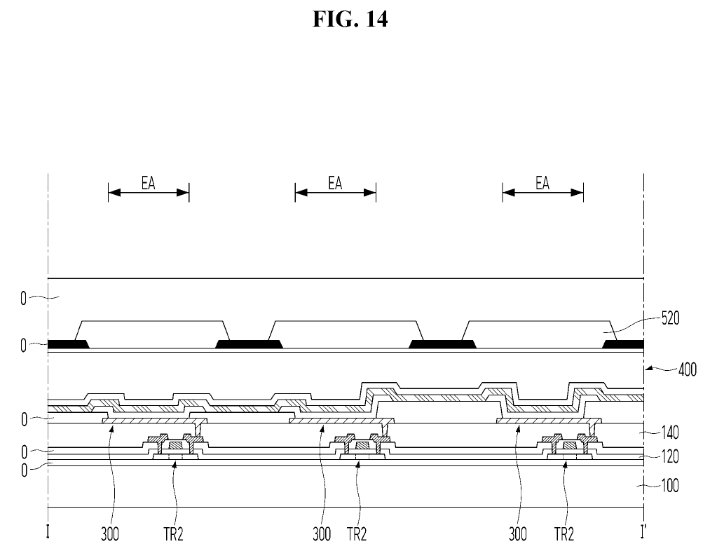

In the display apparatus according to another embodiment of the invention, color filters overlapping with the emission areas EA may be disposed on the pixel areas PA. For example, in the display apparatus according to another embodiment of the invention, a black matrix 510, color filters 520, and filter planarization layer 600 may be disposed on the encapsulation structure 400, as shown in FIG. 14. The black matrix 510 may be disposed adjacent to the encapsulation structure 400. For example, a lower surface of the black matrix 510 toward the device substrate 100 may be in direct contact with the encapsulation structure 400. The black matrix 510 may include a material capable of blocking light. For example, the black matrix 510 may include an absorbing material. The black matrix 510 may overlap with the non-emission area. Thus, in the display apparatus according to another embodiment of the invention, unintended color mixing can be prevented.

The color filters 520 may be disposed side-by-side with the black matrix 510. For example, a portion of the encapsulation structure exposed by the black matrix 510 may be covered by the color filters 520. Each of the color filters 520 may overlap with one of the emission areas EA. Thus, in the display apparatus according to another embodiment of the invention, light emitted from the light-emitting device 300 of each emission area EA may be emitted outside through the color filter 520 overlapping with the corresponding emission area EA. Therefore, in the display apparatus according to another embodiment of the invention, color reproducibility can be improved.

The filter planarization layer 600 may be disposed on the black matrix 510 and the color filters 520. The filter planarization layer 600 may prevent the damage and the deformation of the black matrix 510 and the color filters 520 due to the external impact and moisture. The filter planarization layer 600 may include an insulating material. For example, the filter planarization layer 600 may include an organic insulating material. A thickness difference due to the black matrix 510 and the color filters 520 may be mitigated by the filter planarization layer 600.

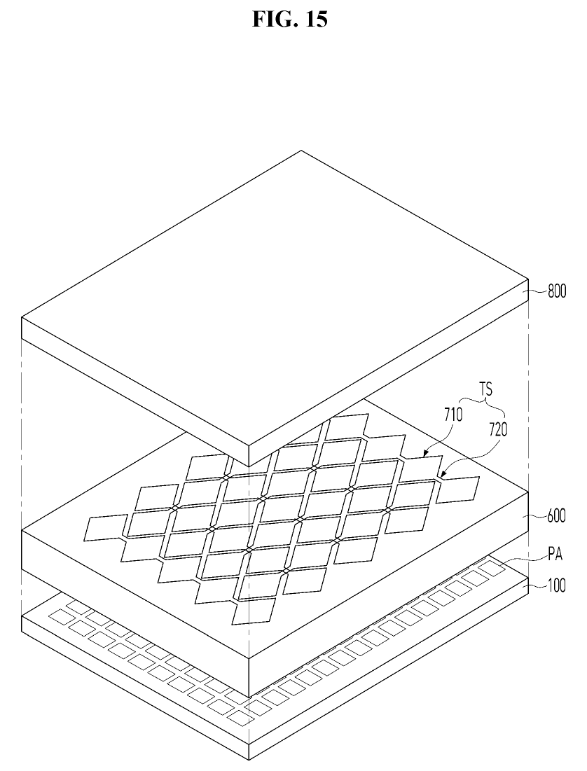

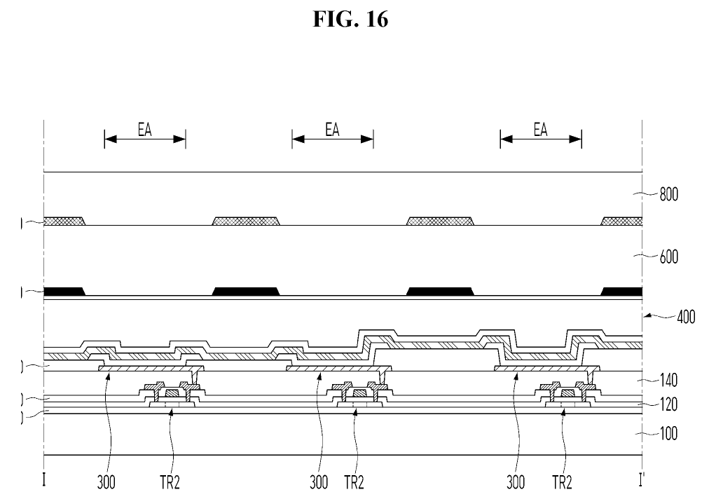

The display apparatus according to another embodiment of the invention may include a touch sensor for sensing a touch of the user or a tool. For example, in the display apparatus according to another embodiment of the invention, a touch sensor TS including touch electrodes 710 and bridge electrodes 720 connecting between the touch electrodes 710 may be disposed on the filter planarization layer 600, as shown in FIGS. 15 and 16.

The touch electrodes 710 and the bridge electrode 720 may include a conductive material. The touch electrodes 710 and the bridge electrode 720 may include a material capable of blocking light. For example, the touch electrodes 710 and the bridge electrodes 720c may an include metal. At least some of the bridge electrodes 720 may include a different material from the touch electrodes 710. For example, at least some of the bridge electrodes 720 may be disposed on a different layer from the touch electrodes 710.

The touch electrodes 710 and the bridge electrodes 720 may not overlap with the emission area EA of each pixel area PA. For example, the touch electrodes 710 and the bridge electrodes 720 may be disposed within the non-emission area. The touch electrodes 710 and the bridge electrode 720 may overlap with the black matrix 510 disposed between the encapsulation structure 400 and the filter planarization layer 600. Thus, in the display apparatus according to another embodiment of the invention, the travelling direction of the light emitted from the light-emitting device 300 of each emission area EA may be limited by the black matrix 510 and the touch sensor TS. For example, in the display apparatus according to another embodiment of the invention, the touch electrodes 710 of the touch sensor TS may function as a light-blocking barrier. Therefore, in the display apparatus according to another embodiment of the invention, unintended color mixing can be effectively prevented.

A touch planarization layer 800 may be disposed on the touch sensor TS. For example, the touch planarization layer 800 may cover the touch electrodes 710 and the bridge electrodes 720 of the touch sensor TS. Damage to the touch electrodes 710 and the bridge electrode 720 due to the external impact and moisture may be prevented by the touch planarization layer 800. The touch planarization layer 800 may include an insulating material. For example, the touch planarization layer 800 may include an organic insulating material. A thickness difference due to the touch electrodes 710 and the bridge electrodes 720 may be mitigated by the touch planarization layer 800.

In some embodiments, the color filters 520 may be omitted. For example, a portion of the encapsulation structure 400 exposed by the black matrix 510 may be in direct contact with the filter planarization layer 600. Thus, in the display apparatus according to another embodiment of the invention, the degree of freedom in the configuration of the encapsulation structure 400 can be improved.

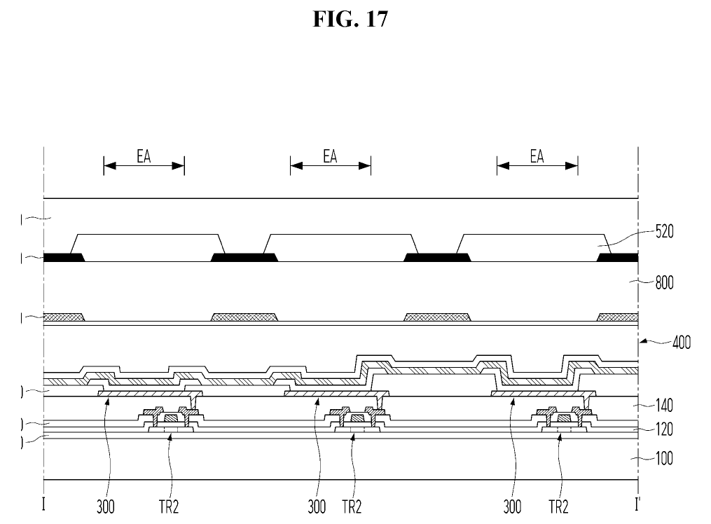

In the display apparatus according to another embodiment of the invention, the touch sensor TS may be disposed closer to the encapsulation structure 400 than the black matrix 510. For example, in the display apparatus according to another embodiment of the invention, the touch electrodes 710 of the touch sensor TS may be disposed side by side on the upper surface of the encapsulation structure 400, the black matrix 510 may be disposed on the touch planarization layer 800 covering the touch electrodes 710, as shown in FIG. 17. A portion of the touch planarization layer 800 exposed by the black matrix 510 may be covered by the color filters 520. The filter planarization layer 600 may be disposed on the black matrix 510 and the color filters 520. For example, the black matrix 510 and the color filters 520 may be disposed between the touch planarization layer 800 and the filter planarization layer 600. Thus, in the display apparatus according to another embodiment of the invention, the reflection of external light due to the touch electrodes 710 may be prevented, and unintended color mixing may be prevented. Therefore, in the display apparatus according to another embodiment of the invention, the quality of the image provided to the user can be improved.

The display apparatus according to embodiments of the invention may include the light-emitting device on the emission area of the device substrate, the bank insulating layer disposed outside the emission area, and the encapsulation structure disposed on the light-emitting device and the bank insulating layer. The emission area may have a curved planar shape, and the bank insulating layer may include the bank opening overlapping with the emission area and the bank groove extending outside from the bank opening. The encapsulation structure may include an organic encapsulating layer. Thus, in the display apparatus according to embodiments of the invention, the unfilled area of the organic encapsulating layer may be removed by the bank groove. Accordingly, the occurrence of spots due to the unfilled area of the organic encapsulating layer may be prevented. In the display apparatus according to embodiments of the invention, a thickness of the encapsulation structure may be reduced, thereby enabling low power operation and low power consumption through reduced light loss due to the encapsulation structure.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
light-emitting devices disposed on emission areas of a device substrate;
an encapsulation structure disposed on the light-emitting devices, the encapsulation structure including an organic encapsulating layer; and
a bank insulating layer disposed between the light-emitting device and the encapsulation structure, the bank insulating layer including bank openings and bank grooves,
wherein:
each of the emission areas defined by the bank openings has a curved planar shape; and
each of the bank grooves extends from one of the bank openings in an outward direction of the corresponding bank opening.

2. The display apparatus according to claim 1, wherein a plane of each of the bank grooves includes an area having a straight shape.

3. The display apparatus according to claim 1, wherein a plane of each of the emission areas has a circular shape.

4. The display apparatus according to claim 3, wherein a width of a plane of each bank groove is less than a diameter of each emission area.

5. The display apparatus according to claim 1, wherein adjacent bank openings contact the same bank groove disposed between the adjacent bank openings.

6. The display apparatus according to claim 1, wherein a plane of each of the bank grooves has a shape in which a width decreases as it moves away from the corresponding bank opening.

7. The display apparatus according to claim 1, wherein the bank insulating layer includes a first portion having a first thickness and a second portion having a second thickness greater than the first thickness.

8. The display apparatus according to claim 7, wherein the first portion of the bank insulating layer overlaps at least one of the bank grooves, and the second portion of the bank insulating layer does not overlap the bank grooves.

9. A display apparatus, comprising:
a device substrate including an emission area having a curved planar shape;
a light-emitting device including a first electrode, a light-emitting unit, and a second electrode, which are sequentially stacked on the emission area;
a bank insulating layer disposed outside the emission area, the bank insulating layer covering an edge of the first electrode; and
an encapsulation structure disposed on the light-emitting device and the bank insulating layer, the encapsulation structure including an organic encapsulating layer,
wherein:
the bank insulating layer includes a first bank region disposed adjacent to the emission area and a second bank region disposed outside the first bank region;
the first bank region includes a first sub-region and a second sub-region having a smaller thickness than the first sub-region; and
each of the first sub-region and the second sub-region includes a portion overlapping with the first electrode.

10. The display apparatus according to claim 9, wherein:
each of the first sub-region and the second sub-region includes an upper surface opposite to the device substrate; and
an upper surface of the second sub-region is disposed closer to the device substrate than an upper surface of the first sub-region.

11. The display apparatus according to claim 9, wherein the first sub-region and the second sub-region are repeatedly arranged along an edge of the emission area.

12. The display apparatus according to claim 9, wherein:
each of the first sub-region and the second sub-region includes a portion disposed outside the first electrode; an
a thickness of the second bank region is substantially equal to a thickness of the first sub-region disposed outside the first electrode.

13. The display apparatus according to claim 9, wherein:
the bank insulating layer includes a first bank layer and a second bank layer disposed on the first bank layer; and
the second bank layer includes a material have an etching selectivity with respect to the first bank layer.

14. The display apparatus according to claim 13, wherein the first bank layer includes a light absorbing material.

15. The display apparatus according to claim 13, wherein the second bank layer is disposed outside the second sub-region.

16. The display apparatus according to claim 9, wherein a thickness of the second sub-region increases in a direction away from the emission area.

17. The display apparatus according to claim 9, wherein a width of the second sub-region decreases in a direction away from the emission area.
